(19) United States
(12) Patent Application Publication
(10) Pub. No.: US 2026/0337815 A1
(43) Pub. Date: Oct. 29, 2026

(54) SUBSTRATE SUPPORT ASSEMBLIES FOR PROCESSING CHAMBERS

(71) Applicant: Applied Materials, Inc., Santa Clara, CA (US)

(72) Inventors: Zhepeng CONG, San Jose, CA (US); Benjamin Ean THAM, Elk Grove, CA (US); Abraham PALATY, San Jose, CA (US)

(21) Appl. No.: 19/188,621

(22) Filed: Apr. 24, 2025

(51) Int. Cl. C30B 25/12; C23C 16/458

(52) U.S. Cl. CPC C30B 25/12; C23C 16/4585

(57) ABSTRACT

An embodiments of a substrate support assembly for a processing chamber includes a shaft extending along a central axis, a plurality of arms coupled to an upper end of the shaft, and a substrate support coupled to the plurality of arms and including a recess that is configured to receive a substrate therein. In addition, the substrate support assembly includes a stiffening member coupled to the plurality of arms axially between the substrate support and the upper end of the shaft so that the stiffening member is contained radially inward from the plurality of arms relative to the central axis. The stiffening member extends radially between the plurality of arms relative to the central axis to increase a rigidity of the plurality of arms.

### CROSS-REFERENCE TO RELATED APPLICATIONS

Not applicable.

### BACKGROUND

Some embodiments disclosed herein generally relate to substrate processing, and more particularly to systems and methods for supporting a substrate in a substrate processing chamber.

Substrates, such as semiconductor substrates, are processed for a wide variety of applications, including the fabrication of integrated devices and microdevices. One such processing operation includes the deposition of films (e.g., metal films, dielectric films, etc.) onto a surface of the substrate. During such an operation, the substrate may be supported in the processing chamber by a substrate support assembly.

### SUMMARY

Some embodiments disclosed herein are directed to a substrate support assembly for a processing chamber that includes a shaft extending along a central axis, a plurality of arms coupled to an upper end of the shaft, and a substrate support coupled to the plurality of arms and including a recess that is configured to receive a substrate therein. In addition, the substrate support assembly includes a stiffening member coupled to the plurality of arms axially between the substrate support and the upper end of the shaft so that the stiffening member is contained radially inward from the plurality of arms relative to the central axis. The stiffening member extends radially between the plurality of arms relative to the central axis to increase a rigidity of the plurality of arms.

Some embodiments disclosed herein are directed to a processing chamber for a substrate that includes a processing volume and a substrate support assembly disposed in the processing volume. The substrate support assembly includes a shaft extending along a central axis, a plurality of arms coupled to an upper end of the shaft, and a substrate support including a recess that is configured to receive a substrate therein. In addition, the substrate support assembly includes a stiffening member coupled to the plurality of arms axially between the substrate support and the upper end of the shaft. The stiffening member having an outer edge that is engaged with a radially inner side of the plurality of arms relative to the central axis. In addition, the stiffening member extends radially between the plurality of arms relative to the central axis to increase a rigidity of the plurality of arms.

Some embodiments disclosed herein are directed to an epitaxial deposition chamber including a processing volume and a substrate support assembly disposed in the processing volume. The substrate support assembly includes a shaft extending along a central axis, a plurality of arms coupled to an upper end of the shaft, and a susceptor including a recess that is configured to receive a substrate therein. In addition, the substrate support assembly includes a stiffening member coupled to the plurality of arms axially between the susceptor and the upper end of the shaft such that the plurality of arms surround an outer edge of the stiffening member. The stiffening member extends radially between the plurality of arms relative to the central axis to increase a rigidity of the plurality of arms, and the stiffening member has an outer diameter that is at least as large as an outer diameter of the recess.

### BRIEF DESCRIPTION OF THE DRAWINGS

For a detailed description of various exemplary embodiments, reference will now be made to the accompanying drawings in which:

FIG. 1 is a partial schematic cross-sectional view of a substrate processing chamber that includes a substrate support assembly according to some embodiments disclosed herein;

FIG. 2 is a perspective view of the arms, shaft, and stiffening member of the substrate support of the processing chamber of FIG. 1 according to some embodiments disclosed herein;

FIG. 3 is a schematic cross-sectional view of the substrate support assembly of the processing chamber of FIG. 1 according to some embodiments disclosed herein; and

FIG. 4 is an enlarged cross-sectional view of a portion of the substrate support assembly of the processing chamber of FIG. 1 according to some embodiments disclosed herein.

### DETAILED DESCRIPTION

A substrate, such as a semiconductor substrate, may be supported in a substrate processing chamber by a substrate support assembly. Some processing chambers, such as those configured to deposit one or more layers of epitaxial films on the substrate, may utilize radiation (including visible, ultraviolet, and/or infrared light) to heat one or more surfaces of the substrate during a processing operation. As a result, at least some of these processing chambers may utilize a substrate support assembly that at least partially exposes multiple surfaces of the substrate to the radiation emitted therein. The structure of existing substrate support assemblies may suffer from poor stability at the increased operational temperatures within the processing chamber. However, additional or more robust structure for the substrate support assembly may result in “shadowing” whereby at least some of the radiation emitted within the processing chamber is blocked from exposure onto the substrate (or underlying support plate) by this additional or more robust structure.

Accordingly, embodiments disclosed herein are directed to substrate support assemblies for substrate deposition chambers that may have improved stability while still allowing the substrate (or an underlying susceptor or support plate therefor) to be exposed to radiation emitted within the processing chamber. In some embodiments, the substrate support assemblies include a plurality of arms for supporting the substrate within the processing chamber, and a stiffening member coupled to and extending laterally between the plurality of arms in order to provide enhanced stability and rigidity to the substrate support assembly. In some embodiments, the stiffening member may comprise a flat plate that is constructed from a transparent or semitransparent material that is configured to allow radiation (e.g., light) to pass therethrough during operations with minimal shadowing on the substrate (or underlying support plate). Thus, by use of the embodiments disclosed herein, a substrate may be better supported in an epitaxial deposition chamber without deteriorating the radiation exposure to the substrate during operations.

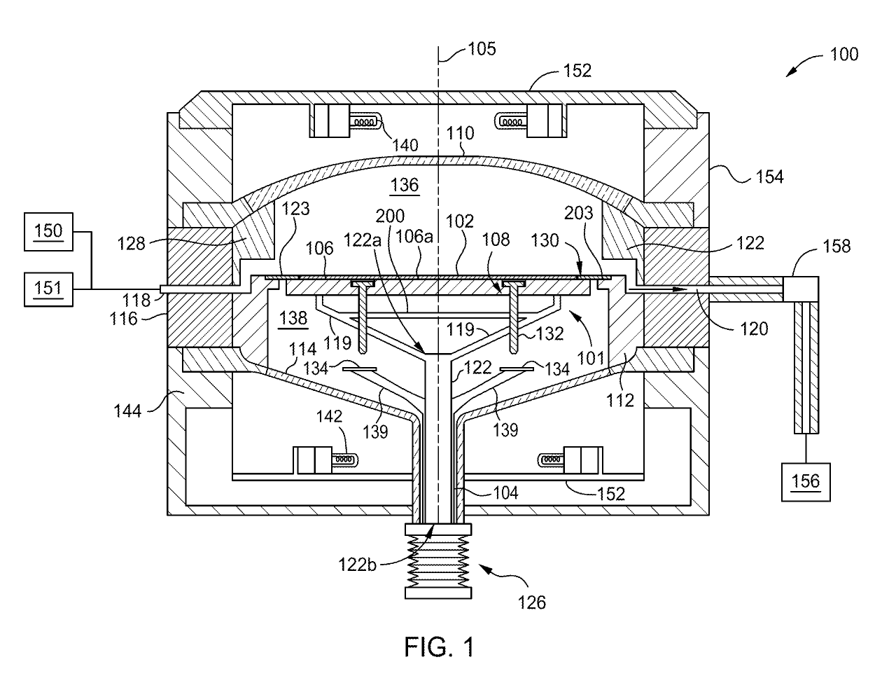

FIG. 1 is a partial schematic side cross-sectional view of a processing chamber 100, according to some embodiments. The processing chamber 100 is a deposition chamber. In one or more embodiments, the processing chamber 100 is an epitaxial deposition chamber that is utilized to grow an epitaxial film on a substrate 102. The processing chamber 100 creates a cross-flow of precursors across a top surface 146 of the substrate 102.

The processing chamber 100 includes a central axis 105 (or “axis 105”), an upper body 154, a lower body 144, and a carrier and feed (CF) ring 116 positioned axially between the upper body 154 and the lower body 144. The upper body 154, the CF ring 116, and the lower body 144 define at least part of a chamber body. A substrate support assembly 101, an upper window 110 (such as an upper dome), a lower window 114 (such as a lower dome), a plurality of upper lamps 140, and a plurality of lower lamps 142.

The processing chamber 100 may also include a lid 152 that further includes a plurality of sensors (not shown) disposed therein for measuring the temperature within the processing chamber 100. The upper window 110 and the lower window 114 are formed of an energy transmissive material, such as quartz. A processing volume 136 and a purge volume 138 are defined between the upper window 110 and the lower window 114. The processing volume 136 and the purge volume 138 are part of an internal volume defined at least partially by the upper window 110, the lower window 114, an upper liner 128, and at least one lower liner 112.

The CF ring 116 includes a plurality of gas inlets 118 and one or more gas exhaust outlets 120. In some embodiments, the plurality of gas inlets 118 are disposed on a radially opposite side of the CF ring 116 from the one or more gas exhaust outlets 120 relative to the central axis 105. A pre-heat ring 123 is disposed below the one or more gas inlets 118 and the one or more gas exhaust outlets 120. The upper liner 128 and the lower liner 112 are disposed on an inner surface of the CF ring 116 and protect the CF ring 116 from reactive gases used during deposition operations or cleaning operations. The gas inlet 118 is positioned to flow a gas radially relative to axis 105 and parallel to the top surface 146 of a substrate 102 disposed within the processing volume 136. The gas inlets 118 are in fluid communication with one or more process gas sources 148 and one or more cleaning gas sources 150. The one or more gas exhaust outlets 120 are in fluid communication with an exhaust pump 156. One or more process gases supplied using the one or more process gas sources 148 can include one or more reactive gases (such as one or more of silicon (Si), phosphorus (P), or germanium (Ge)) or one or more carrier gases (such as one or more of nitrogen (N₂) or hydrogen (H₂)). One or more cleaning gases supplied using the one or more cleaning gas sources 150 can include one or more of hydrogen (H) or chlorine (Cl). In some embodiments, the one or more process gases include silane (SiH₄) or phospine (PH₃), and the one or more cleaning gases include hydrochloric acid (HCl).

The one or more gas exhaust outlets 120 are further connected to or include a high-vacuum pump 158. The high-vacuum pump 158 fluidly connects the one or more gas exhaust outlets 120 and the exhaust pump 156. The high-vacuum pump 158 can assist in the controlled deposition of a layer on the substrate 102. In one or more embodiments, the high-vacuum pump 158 is disposed on a radially opposite side of the processing chamber 100 about the central axis 105, relative to the gas inlets 118.

The substrate support assembly 101 is positioned in the internal volume, axially between the upper window 110 and the lower window 114. The substrate support assembly 101 includes a substrate support 106 that is configured to the substrate 102 in the processing chamber 100 during operations. In some embodiments, the substrate support 106 comprises a susceptor so that the substrate support 106 may be referred to herein as a “susceptor” 106. However, other substrate supports (including, for example, a substrate carrier and/or one or more ring segment(s) that support one or more outer regions of the substrate 102) are also contemplated for the substrate support 106. The substrate support 106 includes an upper surface 106a on which the substrate 102 is supported during operations.

The substrate support assembly 101 also includes a shaft 122 having a first or upper end 122a and a second or lower end 122b opposite and spaced from the upper end 122a along the axis 105. A plurality of arms 119 are coupled to and extend axially upward and radially outward from the upper end 122a of the shaft 122 to engage with and support the substate support 106 in the internal volume of processing chamber. The lower end 122b of shaft 122 is coupled to a motion assembly 126. The motion assembly 126 includes one or more actuators and/or adjustment devices that provide movement and/or adjustment for the shaft 122, arms 119, and substrate support 106 during operations. Specifically, the motion assembly 121 may be configured to axially translate the shaft 122 (and thus also arms 119 and substrate support 106) along axis 105 and may be configured to rotate the shaft 122 (and thus also arms 119 and substrate support 106) about axis 105.

The substrate support 106 may include lift pin holes 108 disposed therein. The lift pin holes 108 are sized to accommodate lift pins 132 for lowering and lifting of the substrate 102 to and from the substrate support 106 before or after a deposition process is performed. The lift pins 132 may rest on lift pin stops 134 when the substrate support 106 is lowered from a process position to a transfer position. The lift pin stops 134 can be coupled to a second shaft 104 through a plurality of arms 139. The second shaft 104 may comprise a hollow, tubular member that receives the shaft 122 axially therethrough so that the shaft 122 is configured to axially slide (along axis 105) and rotate (about axis 105) relative to the second shaft 104 during operations.

In addition, the substrate support assembly 101 includes a stiffening member 200 that is coupled to and that extends radially (or laterally) between the plurality of arms 119. As will be described in more detail below, the stiffening member 200 may be configured to increase the rigidity and stability of the arms 119 so that movement (e.g., wobble) of the substrate support 106 and substrate 102 is reduced (or eliminated) during substrate processing operations. In addition, as will also be described in more detail below, the stiffening member 200 may be constructed from a transparent (or semi-transparent) material that allows light and radiation (e.g., emitted from the plurality of lower lamps 142) to transmit therethrough with minimal shadowing on the substrate support 106 (or substrate 102).

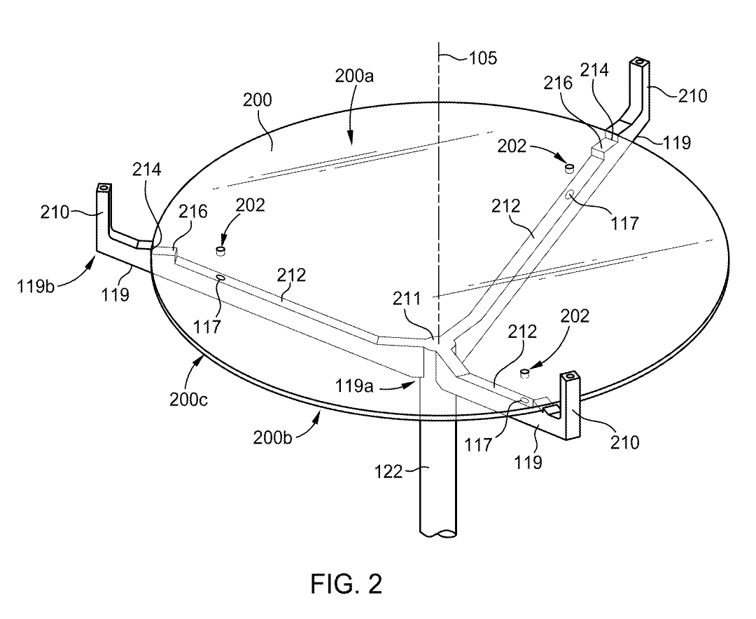

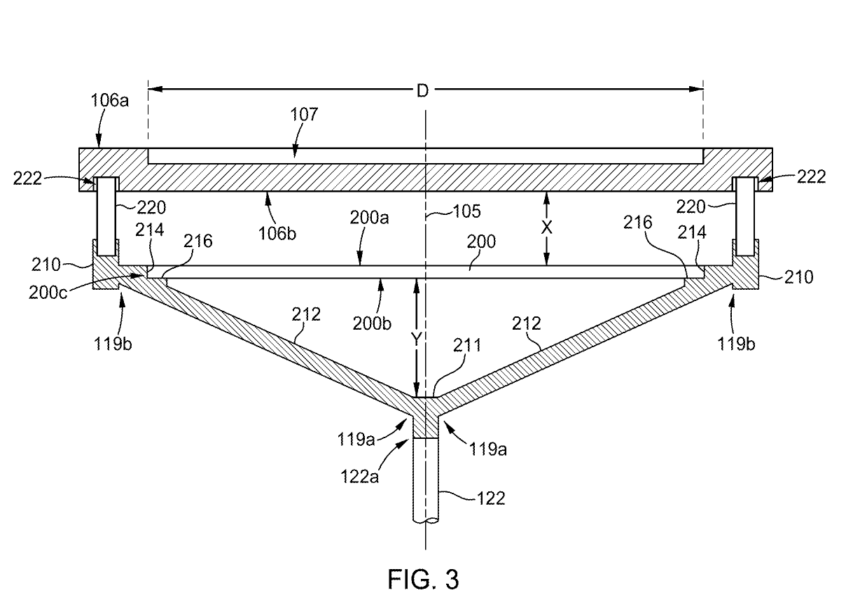

Referring to FIGS. 2 and 3, the stiffening member 200 is shown coupled to the arms 119 of the substrate support assembly 101 according to some embodiments. As best shown in FIG. 2, in some embodiments, the substrate support assembly 101 includes a total of three (3) arms 119 that are uniformly or evenly circumferentially spaced about the central axis 105. Thus, in the embodiment illustrated in FIG. 2, each of the arms 119 is circumferentially spaced about 120 ° about the central axis 105 from each circumferentially adjacent arm 119. However, other numbers and arrangements of arms 119 are contemplated in other embodiments. For instance, in some embodiments, the substrate support assembly 101 includes more than three arms 119, such as four, five, or six arms 119, and/or the arms 119 may have a non-uniform circumferential spacing about the axis 105.

Referring still to FIGS. 2 and 3, each of the arms 119 may have a first or proximal end 119a and a second or distal end 119b opposite the proximal end 119a. The proximal ends 119a of the arms 119 are engaged with a central hub 211 that is further coupled to (or integrated with) the upper end 122a of shaft 122. The distal ends 119b of the arms 119 are projected radially outward and axially upward from the proximal ends 119a. Each arm 119 includes a ramped surface 212 that faces radially inward toward the central axis 105. Thus, the ramped surface 212 of each arm 119 may converge radially inward toward the central axis 105 when moving axially from the distal ends 119b toward the proximal ends 119a and central hub 211. In addition, each of the arms 119 includes an axially extending mounting collar 210 positioned at the distal end 119b.

As shown in FIG. 3, a plurality of mounting pins 220 may be inserted into the mounting collars 210 so that the mounting pins 220 extend axially above the mounting collars 210 relative to axis 105. In some embodiments, the mounting pins 220 may be secured to the mounting collars 210, such as by welding or other suitable processes. The mounting pins 220 may also be received into recesses 222 that extend axially into a lower side 106b of the substrate support 106. A top recess 107 is also defined in the upper side 106a of the substrate support 106 that is configured to receive the substrate 102 (FIG. 1) during operations.

A radially extending shoulder 216 may be defined on each of the arms 119 along the ramped surface 212. In addition, an axially extending alignment surface 214 may also extend axially upward from each of the radially extending shoulders 216. The shoulder 216 of each arm 119 may be spaced between the ends 119a, 119b. For instance, in some embodiments, each shoulder 216 may be positioned more proximate the distal end 119b than the proximal end 119a of the corresponding arm 119. In addition, in some embodiments, each shoulder 216 may be positioned more proximate the proximal end 119a than the distal end 119b of the corresponding arm 119. Further, in some embodiments, each shoulder 216 may be positioned approximately mid-way between the ends 119a, 119b along the corresponding arm 119.

Referring still to FIGS. 2 and 3, in some embodiments, the stiffening member 200 may comprise a circular disk (although, other shapes are contemplated) that includes a first or upper side 200a and a second or lower side 200b that is axially opposite the upper end 200a. The upper side 200a may axially face the lower side 106b of substrate support 106 and the lower side 200b may face axially away from the lower side 106b of substrate support 106, relative to axis 105. In addition, the stiffening member 200 may include a radially outer perimeter or edge 200c that extends axially between the sides 200a, 200b. Because the stiffening member 200 may comprise a circle disk, the outer edge 200c may comprise a cylindrical surface (or a “cylindrical outer edge”). The stiffening member 200 may be positioned on the arms 119 so that the lower side 200b is abutted or engaged with each of the radially extending shoulders 216, and the outer edge 200c is abutted or engaged with the axially extending alignment surfaces 214. Thus, the stiffening member 200 may be contained radially inward or inside of the plurality of arms 119. Also, the arms 119 may surround the outer edge 200c of the stiffening member 200 so that a radially inner side of the arms 119 (specifically, the alignment surfaces 214 defined along the ramped surfaces 212 on the radially inner side of the arms 119 relative to axis 105) may engage or abut the outer edge 200c.

The stiffening member 200 may be further secured to the shoulders 216 and alignment surfaces 214 via welding, brazing, or other suitable connection method or system. Thus, once installed, the stiffening member 200 and arms 119 may define a single-piece body.

The stiffening member 200 may be constructed from a transparent or semi-transparent material, such as quartz. As a result, visible light and/or other radiation (such as ultraviolet and/or infrared radiation) that may be emitted from lower lamps 142 (or other suitable source(s)) may be at least partially transmitted through the stiffening member 200 so as to maintain exposure of the lower side 106b of the substrate support 106 to the light and other radiation during operations. For instance, in some embodiments, the transmission rate of the material of stiffening member 200 may have a transmission rate for a desired wavelength of radiation that is greater than about 90%, such as grater than about 95%, or such as greater than about 98%. In some embodiments, the arms 119 may also be constructed from the same or similar materials as the stiffening member 200. For instance, in some embodiments, the arms 119 may be constructed from quartz that may be transparent or semi-transparent.

In some embodiments, the lamps 142 may comprise quartz lamps that output infrared (IR) radiation, such as IR radiation having a wavelength that is in a range of from about 0.3 micrometers (µm) to about 4.5 µm. Thus, the stiffening member 200 and arms 119 (as well as the lower window 114) may comprise a quartz material with a sufficient transmittance to allow this IR radiation to pass through with no or little absorption. However, the substrate support 106 may comprise silicon carbide (SiC), which may absorb the IR radiation output from the lamps 142 during operations.

As shown in FIG. 3, the stiffening member 200 may have an outer diameter D that extends in a radial direction relative to axis 105 between radially opposing sides of the outer edge 200c. In some embodiments, the diameter D may be at least the same or larger than an outer diameter of the top recess 107, or a substrate 102 that is positioned therein. Without being limited to this or any other theory, sizing the outer diameter D of the stiffening member 200 to be the same or larger than a diameter of the top recess 107 (or a substrate 102 positioned therein) may facilitate a consistent thermal environment across the portion of the lower side 106b of the substrate support 106 that underlies the substrate 102. Specifically, the transparent or semi-transparent material forming the stiffening member 200 may facilitate a “greenhouse” effect within the processing chamber 100 (FIG. 1) whereby heat associated with the radiative energy passing through the stiffening member 200 is at least partially (or temporarily) trapped between the lower side 106b of substrate support 106 and the upper surface 200a of the stiffening member 200. Because the stiffening member 200 is sized (particularly with respect to the outer diameter D) to underly the entire top recess 107 (or a substrate 102 position therein), this trapped thermal energy may facilitate a more consistent and uniform temperature profile along the portion of the lower side 106b of the substrate support 106 underling the substrate 102 during operations. In some embodiments, the outer diameter D may be in a range of from about 250 millimeters (mm) to about 420 mm, such as about 300 mm to about 350 mm, or about 305 mm.

Additionally, in some embodiments, the stiffening member 200, and the greenhouse effect provided thereby, may help to counteract temperature differences across the lower side 106b of the substrate support 106 that may be caused by shadowing by the arms 119 (or other structure(s) positioned below the substrate support 106). Specifically, radiation emitted from the lower lamps 142 (or other suitable source(s)) may be at least partially blocked by the arms 119 (or other structure(s) during operations). However, the greenhouse effect provided by the stiffening member 200 may help to smooth out temperature variations across the lower side 106b that may be caused by any shadowing from the arms 119 (or other structure(s) as previously described).

The axial (or vertical) position of the stiffening member 200 (and thus the shoulders 216 and surfaces 214) may be at least partially dictated by the magnitude of the outer diameter D and the convergence angle of the arms 119 toward the central hub 211. However, in at least some embodiments, the stiffening member 200 may be coupled to the arms 119 so that the upper side 200a of the stiffening member 200 is axially spaced from the lower side 106b of the substrate support 106 by a distance X. While the greenhouse effect previously described above can be useful for facilitating a consistent and uniform thermal environment beneath the substrate support 106, it can cause this region to become relatively hotter than other parts of the processing chamber 100. In some cases, this temperature difference can be problematic for the processing operation (such as for a deposition operation) in the processing chamber 100. Thus, by increasing the distance X, the greenhouse effect facilitated by the stiffening member 200 may be somewhat muted so that a temperature in the region axially between the stiffening member 200 and substrate support 106 may be maintained at a more consistent magnitude relative to a remainder of the processing chamber 100 (or parts thereof). In some embodiments, the distance X may be in a range of from about 10 millimeters (mm) to about 50 mm, or such as about 30 mm to about 50 mm.

Moreover, the lower side 200b of stiffening member 200 may be axially spaced above the central hub 211 by a distance Y. As was previously described for the distance X, the distance Y may also may at least partially be dictated by the magnitude of the outer diameter D and the convergence angle of the arms 119 toward the central hub 211. However, in at least some embodiments, the stiffening member 200 may be coupled to the arms 119 so that the distance Y is sufficiently great enough to avoid (or minimize) shadowing on the lower side 200b of the stiffening member 200 via the central hub 211. For instance, in some embodiments, the distance Y may be in a range of from about 30 mm to about 200 mm, such as about 35 mm to about 185 mm, or such as about 37 mm to about 182 mm.

Further, the stiffening member 200 may also provide additional rigidity to the arms 119 and stability to the substrate support 106 during operations. Specifically, during a deposition operation, the temperature in the processing chamber 100 may become high enough to soften the material of the arms 119. However, interconnection between the stiffening member 200 and the arms 119 may define a truss having a triangular cross-section formed by each circumferentially adjacent pair of arms 119 and the stiffening member 200. This truss may provide additional rigidity to the substrate support assembly 101, despite the material softening caused by the increase operational temperatures of processing chamber 100. As a result, movement or wobble of the substrate 102 and substrate support 106 at elevated temperature during a substrate processing operation may be reduced (or even eliminated) by the inclusion of the stiffening member 200 in the substrate support assembly 101.

Without being limited to this or any other theory, the increased rigidity provided by the stiffening member 200 may allow the length of the arms 119 to be increased to therefore increase the spacing between the central hub 211 and substrate support 106 along axis 105. This increased length of the arms 119 and spacing between central hub 211 and substrate support 106 may reduce shadowing of the arms 119 or central hub 211 on the lower side 106b of the substrate support 106 during operations. Such reduction in shadowing may promote a more uniform temperature across the substrate support 106 which, in turn, may improve a uniformity of deposited film thickness across the substrate 102 (FIG. 1) during operations.

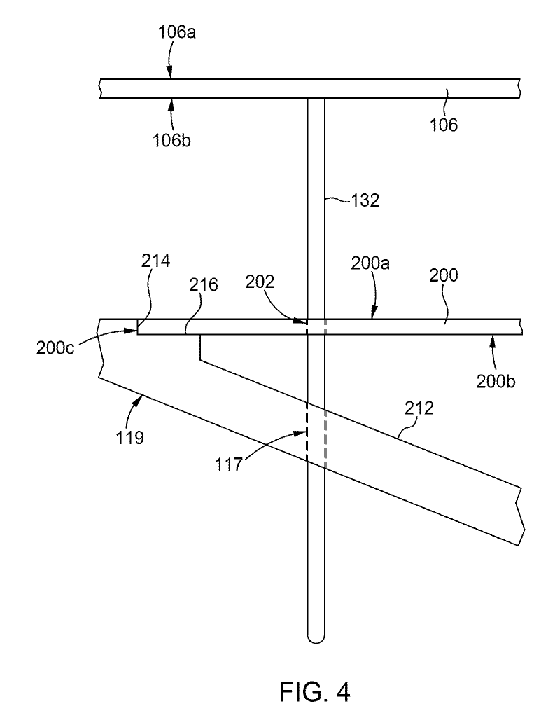

Referring again to FIG. 2, the stiffening member 200 may also include a plurality of holes 202 that extend axially between the sides 200a, 200b. Each of the holes 202 may be circumferentially aligned with the plurality of arms 119 about axis 105. Specifically, referring to FIG. 4, each hole 202 of the stiffening member 200 may receive a corresponding one of the lift pins 132 therethrough during operations. Specifically, each of the arms 119 includes a corresponding axially extending hole 117 for receiving a corresponding lift pin 132 that is aligned with a corresponding one of the holes 202 in the stiffening member 200. Thus, during operations, the lift pins 132 may slide through the aligned holes 117, 202 in the arms 119 and stiffening member 200 and through corresponding holes (not shown) in the substrate support 106 so as to lift the substrate 102 (FIG. 1) from the substrate support 106 as previously described. In some embodiments, each of the holes 117 may be positioned between the shoulders 216 and the proximal end 119a of the corresponding arm 119. Thus, each of the plurality of holes 202 on the stiffening member 200 may be spaced radially inward from the radially extending shoulders 216 on the plurality of arms 119.

Embodiments disclosed herein are directed to substrate support assemblies for substrate deposition chambers that may have improved stability while still allowing the substrate (or an underlying susceptor or support plate therefor) to be exposed to radiation emitted within the processing chamber. In some embodiments, the substrate support assemblies include a plurality of arms for supporting the substrate within the processing chamber, and a stiffening member coupled to and extending laterally between the plurality of arms in order to provide enhanced stability and rigidity to the substrate support assembly. In some embodiments, the stiffening member may comprise a flat plate that is constructed from a transparent or semitransparent material that is configured to allow radiation (e.g., light) to pass therethrough during operations with minimal shadowing on the substrate (or underlying support plate). Thus, by use of the embodiments disclosed herein, a substrate may be better supported in an epitaxial deposition chamber without deteriorating the radiation exposure to the substrate during operations.

The preceding discussion is directed to various embodiments. However, one of ordinary skill in the art will understand that the examples disclosed herein have broad application, and that the discussion of any embodiment is meant only to be exemplary of that embodiment, and not intended to suggest that the scope of the disclosure, including the claims, is limited to that embodiment.

The drawing figures are not necessarily to scale. Certain features and components herein may be shown exaggerated in scale or in somewhat schematic form and some details of conventional elements may not be shown in interest of clarity and conciseness.

In the preceding discussion and in the claims, the terms “including” and “comprising” are used in an open-ended fashion, and thus should be interpreted to mean “including, but not limited to . . . .” Also, the term “couple” or “couples” is intended to mean either an indirect or direct connection. Thus, if a first device couples to a second device, that connection may be through a direct connection of the two devices, or through an indirect connection that is established via other devices, components, nodes, and connections. In addition, as used herein, the terms “axial” and “axially” generally mean along or parallel to a given axis (e.g., central axis of a body or a port), while the terms “radial” and “radially” generally mean perpendicular to the given axis. For instance, an axial distance refers to a distance measured along or parallel to the axis, and a radial distance means a distance measured perpendicular to the axis. Further, when used herein (including in the claims), the words “about,” “generally,” “substantially,” “approximately,” and the like, when used to refer to a stated value, mean within a range of plus or minus 10% of the stated value.

While exemplary embodiments have been shown and described, modifications thereof can be made by one skilled in the art without departing from the scope or teachings herein. The embodiments described herein are exemplary only and are not limiting. Many variations and modifications of the systems, apparatus, and processes described herein are possible and are within the scope of the disclosure. Accordingly, the scope of protection is not limited to the embodiments described herein, but is only limited by the claims that follow, the scope of which shall include all equivalents of the subject matter of the claims. Unless expressly stated otherwise, the operations in a method claim may be performed in any order. The recitation of identifiers such as (a), (b), (c) or (1), (2), (3) before operations in a method claim are not intended to and do not specify a particular order to the operations, but rather are used to simplify subsequent reference to such operations.

What is claimed is:

1. A substrate support assembly for a processing chamber, the substrate support assembly comprising:
a shaft extending along a central axis;
a plurality of arms coupled to an upper end of the shaft;
a substrate support coupled to the plurality of arms, the substrate support including a recess that is configured to receive a substrate therein; and
a stiffening member coupled to the plurality of arms axially between the substrate support and the upper end of the shaft so that the stiffening member is
contained radially inward from the plurality of arms relative to the central axis, the stiffening member extending radially between the plurality of arms relative to the central axis to increase a rigidity of the plurality of arms.

2. The substrate support assembly of claim 1, wherein the stiffening member comprises a material that is configured to allow light to pass therethrough.

3. The substrate support of claim 1, wherein the stiffening member comprises quartz.

4. The substrate support of claim 1,
wherein each of the plurality of arms includes a proximal end that is coupled to the upper end of the shaft, a distal end that is projected away from the proximal end, and a ramped surface that converged radially inward toward the central axis when moving from the distal end to the proximal end,
wherein each of the plurality of arms includes a radially extending shoulder defined on the ramped surfaces, and
wherein a lower side of the stiffening member is engaged with the radially extending shoulder on each of the plurality of arms.

5. The substrate support of claim 4, wherein the lower side of the stiffening member is welded to the radially extending shoulder on each of the plurality of arms.

6. The substrate support of claim 4,
wherein the stiffening member comprises a circular disk that includes a cylindrical outer edge,
wherein each of the plurality of arms includes an alignment surface extending axially from the radially extending shoulder, and
wherein the cylindrical outer edge is engaged with the alignment surface on each of the plurality of arms.

7. The substrate support of claim 6, wherein the stiffening member further comprises a plurality of holes that are configured to receive a lift pin therethrough, wherein the plurality of holes are spaced radially inward from the radially extending shoulders of the plurality of arms.

8. A processing chamber for a substrate, the processing chamber comprising:
a processing volume;
a substrate support assembly disposed in the processing volume, the substrate support assembly comprising:
a shaft extending along a central axis;
a plurality of arms coupled to an upper end of the shaft;
a substrate support including a recess that is configured to receive a substrate therein; and
a stiffening member coupled to the plurality of arms axially between the substrate support and the upper end of the shaft, the stiffening member having an
outer edge that is engaged with a radially inner side of the plurality of arms relative to the central axis, and the stiffening member extending radially between the plurality of arms relative to the central axis to increase a rigidity of the plurality of arms.

9. The processing chamber of claim 8, further comprising a lamp positioned below the processing volume, wherein the lamp is configured to emit radiation, and wherein the stiffening member is configured to allow at least some of the radiation to transmit therethrough to heat a lower surface of the substrate support.

10. The processing chamber of claim 9, wherein the stiffening member comprises quartz.

11. The processing chamber of claim 10,
wherein each of the plurality of arms includes a proximal end that is coupled to the upper end of the shaft, a distal end that is projected away from the proximal end, and a ramped surface that converged radially inward toward the central axis when moving from the distal end to the proximal end,
wherein each of the plurality of arms includes a radially extending shoulder defined on the ramped surfaces, and
wherein a lower side of the stiffening member is engaged with the radially extending shoulder on each of the plurality of arms.

12. The processing chamber of claim 11, wherein the lower side of the stiffening member is welded to the radially extending shoulder on each of the plurality of arms.

13. The processing chamber of claim 11,
wherein the stiffening member comprises a circular disk such that the outer edge comprises a cylindrical outer edge,
wherein each of the plurality of arms includes an alignment surface extending axially from the radially extending shoulder, and
wherein the cylindrical outer edge is engaged with the alignment surface on each of the plurality of arms.

14. The processing chamber of claim 13,
wherein the stiffening member further comprises a plurality of holes that are spaced radially inward from the radially extending shoulders of the plurality of arms; and
wherein the processing chamber further comprises a plurality of lift pins extending through the substrate support and through the plurality of holes.

15. The processing chamber of claim 14, wherein each of the plurality of arms includes a hole that is configured to receive a corresponding one of the lift pins therethrough.

16. An epitaxial deposition chamber comprising:
a processing volume;
a substrate support assembly disposed in the processing volume, the substrate support assembly comprising:
a shaft extending along a central axis;
a plurality of arms coupled to an upper end of the shaft;
a susceptor including a recess that is configured to receive a substrate therein; and
a stiffening member coupled to the plurality of arms axially between the susceptor and the upper end of the shaft such that the plurality of arms surround an
outer edge of the stiffening member, the stiffening member extending radially between the plurality of arms relative to the central axis to increase a rigidity of the plurality of arms, and the stiffening member having an outer diameter that is at least as large as an outer diameter of the recess.

17. The epitaxial deposition chamber of claim 16, wherein the stiffening member has an upper surface and a lower surface, the upper surface axially facing a lower surface of the susceptor, and the upper surface of the stiffening member being axially spaced from the lower surface of the susceptor by a distance that is in a range of from about 30 millimeters (mm) to about 70 mm.

18. The epitaxial deposition chamber of claim 17, further comprising a lamp positioned below the processing volume, wherein the lamp is configured to emit radiation, and wherein the stiffening member is configured to allow at least some of the radiation to transmit therethrough to heat a lower surface of the susceptor.

19. The epitaxial deposition chamber of claim 17,
wherein each of the plurality of arms includes a proximal end that is coupled to the upper end of the shaft, a distal end that is projected away from the proximal end, and a ramped surface that converges radially inward toward the central axis when moving from the distal end to the proximal end,
wherein each of the plurality of arms includes a radially extending shoulder defined on the ramped surfaces, and
wherein a lower side of the stiffening member is engaged with the radially extending shoulder on each of the plurality of arms.

20. The epitaxial deposition chamber of claim 19,
wherein the stiffening member comprises a circular disk such that the outer edge comprises a cylindrical outer edge,
wherein each of the plurality of arms includes an alignment surface extending axially from the radially extending shoulder, and
wherein the cylindrical outer edge is engaged with the alignment surface on each of the plurality of arms.
